(19) United States
(12) Patent Application Publication
(10) Pub. No.: US 2014/0342178 A1
(43) Pub. Date: Nov. 20, 2014

(54) ELECTROLYTIC COPPER FOIL, AND CIRCUIT BOARD AND FLEXIBLE CIRCUIT BOARD USING THE ELECTROLYTIC COPPER FOIL

(71) Applicant: Takahiro Saito, Tokyo (JP)

(72) Inventor: Takahiro Saito, Tokyo (JP)

(73) Assignee: FURUKAWA ELECTRIC CO., LTD., Tokyo (JP)

(21) Appl. No.: 14/129,287

(22) PCT Filed: Jun. 27, 2012
(86) PCT No.: PCT/JP2012/066416

§ 371 Date: Feb. 19, 2014

(30) Foreign Application Priority Data
Jun. 28, 2011 (JP) 2011-143337

(51) Int. Cl. H05K 1/02; H05K 1/09

(52) U.S. Cl. CPC H05K 1/028; H05K 1/09
USPC 428/606

(57) ABSTRACT

The present invention provides an electrodeposited copper foil for a flexible wiring board, wherein handling in manufacturing and processing lines is easy, good bending and flexing are provided with heating during a film adhesion step, small electric devices can be accommodated, excessive coarsening of a crystal grain structure is minimized, and excellent fine pattern characteristics are provided. The electrodeposited copper foil of the present invention having excellent bending and flexing characteristics is such that a crystal distribution before heating (unprocessed) is such that a number of crystal grains less than 2 μm in diameter within a range of 300 μm×300 μm is 10,000 or greater and 25,000 or less, and a crystal distribution after heating for 1 hr at 300° C. is such that the number of crystal grains less than 2 μm in diameter within a range of 300 μm×300 μm is 5,000 or greater and 15,000 or less. The electrodeposited copper foil of the present invention is characterized in that a crystal orientation ratio (%) as measured by EBSD before heating (unprocessed) to that after heating for 1 hr at 300° C. is such that ratios of change after heating relative to before heating for the following totals:
a total of the (001) plane and the (311) plane,
a total of the (011) plane and the (210) plane, and
a total of the (331) plane and the (210) plane
are all within ±20%.

### TECHNICAL FIELD

The present invention relates to an electrodeposited copper foil with excellent bending, flexing, and fine pattern characteristics, and a manufacturing method therefor. To describe this in more detail, the present invention relates to an electrodeposited copper foil suitable for use in a flexible wiring board with excellent bending, flexing, and fine pattern characteristics, in which excessive coarseness of crystals is minimized during a heating process applied during a film adhesion step when manufacturing the flexible wiring board.

### BACKGROUND ART

Wiring boards are used in various types of electronic devices as substrates and connection materials for silicon chips, capacitors, and the like, and copper foil is generally used for conductive layers in the wiring boards.

The copper foil of the wiring board is generally supplied in the form of rolled copper foil or electrodeposited copper foil, but electrodeposited copper foil is widely used for its high productivity and the ease with which it can be made thin.

As high-functionality electronic devices, including information device terminals, become smaller and smaller, the volume of the interior of the devices has become a problem. Therefore, wiring boards (hereafter referred to as “flexible wiring boards”), which are required to have good bending and flexibility for such uses, are required to have good bending and flexibility in the copper foil used in conductive layers therein as well.

Copper foil is generally subject to a thermal history around 300° C. during a film adhesion step and other steps when applying the copper foil to such flexible wiring boards. Control of the copper foil characteristics after being subjected to such a thermal history is therefore important. Specifically, for uses which require good bending and flexibility, a copper foil is needed which is soft and has a coarse crystal grain structure and therefore few grain boundaries which would act as origin points for cracks. Note that the modulus of elasticity, which is an indicator of softness in electrodeposited copper foil, correlates well with the 0.2% yield strength; if a copper foil has a low 0.2% yield strength, it can be judged as being a soft copper foil with a low modulus of elasticity.

However, softness of the copper foil is a characteristic needed after passing through a film adhesion step. If the copper foil is excessively soft before the film adhesion step, it will tend to wrinkle causing problems with handling in the manufacturing and processing lines. Conversely, if the copper foil is excessively hard before the film adhesion step, the foil will tend to crack in the manufacturing and processing lines, creating problems with handling.

In addition, it is necessary to be able to form a fine pattern circuit that can accommodate higher-density wiring when the copper foil is used in a flexible wiring board, the copper foil must therefore have low coarseness. Furthermore, the crystal grain structure in the copper foil must be fine to a certain degree. If the copper foil has an excessively coarse crystal grain structure due to the heating process, this will adversely affect the fine pattern characteristics.

Furthermore, in order to improve the fine pattern characteristics, it is also necessary to make the copper foil thin. In other words, the thickness of the copper foil used in flexible wiring boards has conventionally been 18 μm or 12 μm, but there is now more demand for 12 μm or thinner copper foil. However, manufacturing costs for rolled copper foil with a thickness of 18 μm or lower is approximately double that of electrodeposited copper foil. Moreover, recent research has shown that rolled copper foil cannot necessarily be said to have better bending resistance than electrodeposited copper foil.

Patent Document 1 (Japanese Unexamined Patent Application Publication No. 2009-185384A) discloses that the bending resistance of an electrodeposited copper foil involves adjusting factors such as surface roughness for an S-surface (shiny surface) and an M-surface (matte surface), carbon and sulfur content, weight deviation, crystal orientation, flexion factor, Vickers hardness, number of nodules per unit area, and so on. However, cutting-edge research of the present inventors has recently shown that an increase in the coarseness due to heating of fine crystals affects the bending resistance of flexible wiring boards.

Patent Document 2 (Japanese Patent No. 3346774) discloses an electrodeposited copper foil in which the crystal grain diameter on the matte surface of the copper foil is refined, thereby reducing surface roughness and improving the tensile strength after heating. This is in order to improve etching characteristics limited to use in refining circuits, but does not necessarily lead to an increase in bending resistance. Therefore, this copper foil is characterized in that the copper crystals are preferentially oriented in the (220) plane.

Patent Document 3 (Japanese Unexamined Patent Application Publication No. 2010-037654A) discloses an electrodeposited copper foil, wherein a crystal structure after heating is such that a crystal grain diameter is 5 μm or more. The electrodeposited copper foil is disclosed as being an electrodeposited copper foil in which the crystal grain diameter is coarsened, and therefore has good flexibility and bending resistance. However, excessively coarsening the crystal grain diameter adversely effects the fine pattern characteristics.

### PRIOR ART DOCUMENTS

### Patent Documents

Patent Document 1: Japanese Unexamined Patent Application Publication No. 2009-185384A

Patent Document 2: Japanese Patent No. 3346774

Patent Document 3: Japanese Unexamined Patent Application Publication No. 2010-037654A

### SUMMARY OF THE INVENTION

### Problems to be Solved by the Invention

The present invention provides an electrodeposited copper foil for a flexible wiring board, wherein handling in manufacturing and processing lines is easy, good bending and flexing are provided with heating during a film adhesion step, small electric devices can be accommodated, excessive coarsening of a crystal grain structure is minimized, and excellent fine pattern characteristics are provided.

### Means for Solving the Problem

The electrodeposited copper foil of the present invention is characterized in that a crystal distribution before heating (unprocessed) is such that a number of crystal grains less than 2 μm in diameter within a range of 300 μm×300 μm is 10,000 or greater and 25,000 or less, and a crystal distribution after heating for 1 hr at 300° C. is such that the number of crystal grains less than 2 μm in diameter within a range of 300 μm×300 μm is 5,000 or greater and 15,000 or less.

The electrodeposited copper foil of the present invention is characterized in that a crystal orientation ratio (%) as measured by EBSD before heating (unprocessed) to that after heating for 1 hr at 300° C. of the copper foil is such that ratios of change after heating relative to before heating for the following totals:

a total of the (001) plane and the (311) plane,

a total of the (011) plane and the (210) plane, and

a total of the (331) plane and the (210) plane

are all within ±20%.

The 0.2% yield strength (MPa) of the electrodeposited copper foil after heating for 1 hr at 300° C. is less than or equal to a value y in the equation below. Where x is a thickness (μm) of the foil.

y=215*x^{-0.2} (Equation 1)

A surface roughness Rz of an M-surface of the electrodeposited copper foil is preferably less than 3.0 μm and the surface roughness Rz of an S-surface is preferably less than 3.0 μm.

The electrodeposited copper foil of the present invention is suitably used as a wiring board and is particularly suited to use as a flexible wiring board.

### Effects of the Invention

The present invention provides an electrodeposited copper foil for a flexible wiring board, wherein handling of the wiring board in manufacturing and processing lines is easy, good bending and flexibility are provided with heating during a film adhesion step, small electric devices can be accommodated, excessive coarsening of a crystal grain structure is minimized, and excellent fine pattern characteristics are provided.

### BRIEF DESCRIPTION OF THE DRAWING

FIG. 1 is an explanatory diagram showing a drum-type foil manufacturing device.

### BEST MODE FOR CARRYING OUT THE INVENTION

The electrodeposited copper foil of the present invention is such that a crystal distribution before heating (unprocessed) is such that a number of crystal grains less than 2 μm in diameter within a range of 300 μm×300 μm is 10,000 or greater and 25,000 or less, and a crystal distribution after heating for 1 hr at 300° C. is such that the number of crystal grains less than 2 μm in diameter within a range of 300 μm×300 μm is 5,000 or greater and 15,000 or less.

If the number of crystal grains less than 2 μm in diameter within a range of 300 μm×300 μm is less than 10,000 before heating, the crystal grain structure of the copper foil before film adhesion is excessively coarse, resulting in low yield strength and a tendency to wrinkle in manufacturing and processing lines, which makes handling difficult. On the other hand, if the number of crystal grains less than 2 μm in diameter within a range of 300 μm×300 μm before heating exceeds 25,000, the crystal grain structure before heating is excessively fine, causing insufficient ductility and resulting in a tendency to crack in manufacturing and processing lines, which makes handling difficult. Handling is easy in manufacturing and processing lines, however, when the number of crystal grains less than 2 μm in diameter within a range of 300 μm×300 μm before heating is 10,000 or greater and 25,000 or less.

If the number of crystal grains less than 2 μm in diameter within a range of 300 μm×300 μm is less than 5,000 after heating for 1 hr at 300° C., the crystal grain structure is excessively coarse, which adversely affects fine pattern characteristics. If the number exceeds 15,000, the crystal grain structure becomes excessively fine, resulting in an increase in grain boundaries, which become origin points for cracks, which adversely affects bending and flexing characteristics.

If the number of crystal grains less than 2 μm in diameter within a range of 300 μm×300 μm is 5,000 or greater and 15,000 or less after heating for 1 hr at 300° C., bending and flexing characteristics as well as fine pattern characteristics are excellent.

Note that in the specification, “unprocessed” means a state after formation of the foil, or after rust-proofing the surface after formation, or, as needed, after a roughening treatment, and before a heating process, which is discussed below.

The electrodeposited copper foil of the present invention is characterized in that a crystal orientation ratio (%) as measured by EBSD before heating (unprocessed) to that after heating for 1 hr at 300° C. is such that ratios of change after heating relative to before heating for the following totals:

a total of the (001) plane and the (311) plane,

a total of the (011) plane and the (210) plane, and

a total of the (331) plane and the (210) plane

are all within ±20%.

These limitations are used because if any of those ratios of change exceeds ±20%, wrinkling and curling tend to occur due to the thermal history applied during a film adhesion step, which is not preferable.

The electrodeposited copper foil of the present invention is characterized in that the 0.2% yield strength after heating a foil having a thickness x (μm) for 1 hr at 300° C. is less than or equal to a value y in equation 1 given below.

With a thickness x (μm) of the foil, the 0.2% yield strength of the electrodeposited copper foil after heating for 1 hr at 300° C. is less than or equal to the value y given in equation 1 below, but if it exceeds the value y, the modulus of elasticity increases, adversely affecting the bending and flexing characteristics.

y=215*x^{-0.2} (1)

A surface roughness Rz of an M-surface of the electrodeposited copper foil of the present invention is less than 3.0 μm and the surface roughness Rz of an S-surface is less than 3.0 μm.

The reason the surface roughness Rz for both is less than 3.0 μm is because, if Rz exceeds 3.0 μm, origin points for cracks tend to appear in the surface of the copper foil, causing unevennesses, which adversely affects bending and fine pattern characteristics.

An embodiment of the present invention is described in detail below.

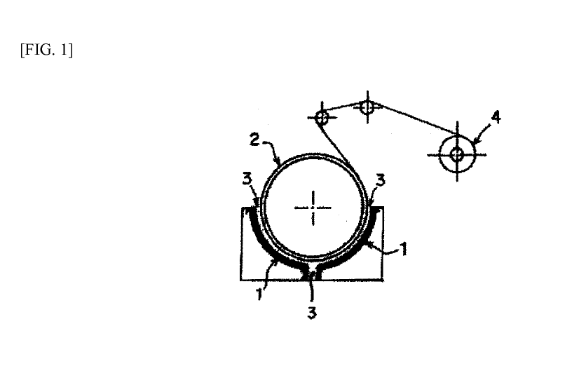

Electrodeposited copper foil is typically made using an electrolytic foil manufacturing device as shown in FIG. 1, for example. The electrolytic foil manufacturing device comprises a rotating drum-shaped cathode 2 (whose surface is SUS or titanium), and an anode 1 (a lead electrode a titanium electrode covered with a precious metal oxide) which is disposed concentrically with respect to the cathode 2. Copper is electrodeposited to a predetermined thickness on the surface of the cathode 2 by applying a current between the electrodes while supplying an electrolyte 3 to the foil manufacturing device. The copper is peeled from the surface of the cathode 2 as a foil. A copper foil 4 at this point is sometimes called an untreated electrodeposited copper foil. A surface of the untreated electrodeposited copper foil 4 in contact with the electrolyte 3 is called a matte surface (hereafter called an M-surface) and a surface in contact with the drum-shaped cathode 2 is called a shiny surface (hereafter called an S-surface). Note that, a description of a foil manufacturing device using a drum-shaped cathode 2 was described above, but copper foil is also sometimes manufactured using a foil manufacturing device with a plate-like cathode.

To make an electrodeposited copper foil with the device shown in FIG. 1, a copper sulfate plating solution is used as the electrolyte 3. The sulfuric acid concentration in the copper sulfate plating solution is preferably from 20 to 150 g/L and more preferably from 30 to 100 g/L. If the sulfuric acid concentration is 20 g/L or less, the current does not flow as easily, making realistic operation difficult. The uniformity and electrodeposition characteristics of the plating are also adversely affected. If the sulfuric acid concentration exceeds 150 g/L, the solubility of the copper drops, making it impossible to achieve sufficient copper concentration, which in turn makes realistic operation difficult. Machinery corrosion is also accelerated.

A copper concentration is preferably from 40 to 150 g/L and more preferably from 60 to 100 g/L. If the copper concentration is lower than 40 g/L, it becomes difficult to ensure a current density sufficient to allow realistic operation in manufacturing electrodeposited copper foil. Raising the copper concentration higher than 150 g/L is unrealistic as this requires an extremely high temperature.

Organic additives and chlorine are added to the copper sulfate plating solution. There are two types of organic additives added to the copper sulfate plating solution, compounds having a mercapto group and polymer polysaccharides. Compounds with a mercapto group have the effect of promoting electrodeposition of copper, and polymer polysaccharides have the effect of suppressing electrodeposition of copper. When both promotion and suppression effects are provided appropriately, electrodeposition of copper is promoted in recesses created during manufacturing of the foil, and electrodeposition of copper on bumps is suppressed, resulting in a smoothing effect of the deposition surface. Moreover, the crystal structure control effect thus provided when the concentrations of the two organic additives are appropriate allows the obtaining of an electrodeposited copper foil in which excessive fineness or coarseness of the crystal grain structure before and after heating is suppressed, changes in the crystal orientation ratio before and after heating are suppressed, and a low 0.2% yield strength and low roughness are obtained, which is a feature of the present invention. The chlorine that is added acts as a catalyst that enables the effects of the two organic additives.

For the compound having a mercapto group, MPS-Na (sodium 3-mercapto-1-propanesulfonate) or SPS-Na {sodium bis(3-sulfopropyl)disulfide} can be selected. In terms of organic structure, SPS is a dimer of MPS and has the same concentration needed for obtaining the same effect as an additive. Preferable concentrations are 0.25 ppm or greater and 7.5 ppm or less and more preferable concentrations are 1.0 ppm or greater and 5.0 ppm or less. At less than 0.25 ppm, it is difficult to achieve the electrodeposition promoting effect with respect to recesses created when making the foil, making it difficult to achieve the effect of controlling the crystal structure, which is a feature of the present invention. At more than 7.5 ppm, the effect of promoting electrodeposition is too prominent on bumps, with a tendency for partial abnormal precipitation to occur. Therefore, production of a copper foil having a normal appearance becomes difficult and improvement in physical properties cannot be expected while the cost of the additives increases.

The polymer polysaccharide is HEC (hydroxyethyl cellulose), preferably with a concentration of 3.0 ppm or greater and 30 ppm or less, and more preferably 10 ppm or greater and 20 ppm or less. At less than 3.0 ppm, it is difficult to achieve the electrodeposition suppression effect with respect to bumps, making it difficult to achieve the effect of controlling the crystal structure, which is a feature of the present invention. At more than 30 ppm, there is an excess of frothing, which is an effect unique to polymer polysaccharides. There is also insufficient supply of copper ions and not only is making a normal copper foil difficult, the amount of organic matter in the electrolyte increases, which is a cause of burnt deposits.

Chlorine is added to the electrolyte. Preferable concentrations of the chlorine are 1 ppm or greater and 20 ppm or less and more preferable concentrations are 5 ppm or greater and 15 ppm or less. The chlorine acts as a catalyst that enables the effects of the two organic additives. A chlorine concentration of less than 1 ppm makes it difficult to achieve the catalytic action, which not only makes it difficult to achieve the effect of the organic additives, but also makes management and control difficult due to the extremely low concentration, which is unrealistic. A concentration of greater than 20 ppm, on the other hand, creates an excessive effect not only of the catalytic action of the chlorine on the organic additive, but also on the electrodeposition of the chlorine itself, making it difficult to achieve the effect of crystal structure control by the additives, which is a feature of the present invention.

The current density for making the foil is preferably from 20 to 200 A/dm², and particularly preferably from 30 to 120 A/dm². If the current density is less than 20 A/dm², the production efficiency during manufacturing of the electrodeposited copper foil is extremely low and unrealistic. To raise the current density above 200 A/dm², very high copper concentration, high temperature, and high flow rate are needed, which places a very large load on the electrodeposited copper foil making facility, which is unrealistic.

The temperature for the electrolytic bath is preferably from 25 to 80° C. and more preferably from 30 to 70° C. If the bath temperature is less than 25° C., it is difficult to ensure sufficient copper concentration and current density when manufacturing the electrodeposited copper foil, which is unrealistic. Raising the temperature of the electrolytic bath above 80° C. creates extreme difficulties in terms of operation and of machinery, which is unrealistic. These electrolysis condition are adjusted with the ranges given as appropriate such that problems such as precipitation of the copper, burning of plating, and so on do not occur.

Because the surface roughness of the electrodeposited copper foil immediately after manufacturing transfers the roughness of the surface of the cathode 2, it is preferable to use a cathode that has a surface roughness Rz of 0.1 to 3.0 μm. Since the surface roughness of the S-surface of the electrodeposited copper foil immediately after manufacturing is a transfer of the cathode surface, by using this kind of cathode, it is possible to set the surface roughness Rz of the S-surface to 0.1 to 3.0 μm. The surface roughness Rz of the S-surface of the electrodeposited copper foil is 0.1 μm or less means making the surface roughness Rz of the cathode to be 0.1 μm or less. This is because, considering the current grinding techniques and the like, it is difficult to make a finish smoother than 0.1 μm, and making such would also be unsuitable for mass production. Furthermore, if the roughness Rz of the S-surface is 3.0 μm or greater, cracks tend to form during bending or folding and the fine pattern characteristics diminish due to the greater unevenness, making it impossible to achieve the characteristics required by the present invention.

The roughness Rz of the M-surface of the electrodeposited copper foil is desirably from 0.05 to 3.0 μm. If the roughness Rz is less than 0.05 μm, realistic manufacturing is almost impossible due to the extreme difficulty even if a glossy plating is used. Furthermore, if the roughness Rz of the M-surface is 3.0 μm or greater, cracks tend to form during bending or folding and the fine pattern characteristics diminish due to the greater unevenness, making it impossible to achieve the characteristics required by the present invention. The S-surface and the M-surface more favorably have a roughness Rz of less than 1.5 μm.

Furthermore, the thickness of the electrodeposited copper foil is desirably from 3 μm to 210 μm. A copper foil with a thickness of less than 3 μm will have very strict manufacturing conditions due to handling technologies, and would therefore not be realistic. The upper limit on thickness is around 210 μm, based on current circuit board usage. It is difficult to conceive of an electrodeposited copper foil having a thickness of 210 μm or greater being used as a copper foil for a wiring board, and there would be no cost benefits of using such an electrodeposited copper foil.

The present invention is described below with reference to examples, but the present invention is not limited to these examples.

### (1) Foil Making

### Working Examples 1 to 7, Comparative Examples 1 to 6, and Reference Example

Table 1 gives manufacturing conditions such as electrolyte composition, etc. An electrodeposited copper foil with a thickness of 12 μm was made by passing the copper sulfate plating solutions having the compositions shown in Table 1 through an activated carbon filter, subjected to a washing processes, endowed with predetermined concentrations by adding additives shown in Table 1, and made into an electrodeposited copper foil with a rotating drum-type foil manufacturing device shown in FIG. 1 using current densities shown in Table 1. Note that the precipitation face (S-surface) of the drum was subjected to a polishing process with a polishing cloth before making the foil. When doing the polishing, a #1500 polishing cloth was used for Working Examples 1 to 6, Comparative Examples 1 to 6, and the Reference Example and a #800 polishing cloth was used for Working Example 7.

Furthermore, as a Reference Example, an untreated electrodeposited copper foil with a thickness of 12 μm was made according to the Reference Example 4 of Patent Document 3 (Japanese Unexamined Patent Application Publication No. 2010-037654A). The Reference Example (see Table 4) had important additive compositions that differed from the present invention. There were two additives: a reactant of 1,3-dibromopropane and piperazine, and MPS.

TABLE 1
Common Electrolysis Conditions

| Cu | H₂SO₄ | Bath temperature | Current density |
|---|---|---|---|
| (g/L) | (g/L) | (° C.) | (A/dm²) |
| 70 | 50 | 45 | 40 |

| | Compound having | Polymer | |
|---|---|---|---|
| | a mercapto group | polysaccharide | Chlorine |
| | MPS | HEC | Chlorine ions |
| No. | (ppm) | (ppm) | (ppm) |
| Working | 2.5 | 5.0 | 10 |
| example-1 | | | |
| Working | 2.5 | 20.0 | |
| example-2, 7 | | | |
| Working | 0.5 | 5.0 | |
| example-3 | | | |
| Working | 0.5 | 20.0 | |
| example-4 | | | |
| Working | 5.0 | 5.0 | |
| example-5 | | | |
| Working | 5.0 | 20.0 | |
| example-6 | | | |
| Comparative | 2.5 | 1.0 | |
| example-1 | | | |
| Comparative | 0.1 | 15.0 | |
| example-2 | | | |
| Comparative | 2.5 | 15.0 | 0.2 |
| example-3 | | | |
| Comparative | 2.5 | 15.0 | 40 |
| example-4 | | | |
| Comparative | 0.1 | 5.0 | 10 |
| example-5 | | | |
| Comparative | 0 | 0 | 0 |
| example-6 | | | |

The untreated electrodeposited copper foil of the working examples, comparative examples, and reference example were divided into six samples and used in the following measurements and tests as needed.

First, one sample was used to measure surface roughness.

Next, one of the unused sample was further divided into two, one part being left as-is (i.e., unheated), and one heated for 1 hr at 300° C. before being subjected to EBSD measurement to calculate a crystal orientation ratio and a crystal grain diameter distribution.

One of the unused sample was thermally compressed onto a film and etched, after which fine pattern characteristics were evaluated.

One of the unused sample was further divided into two, one part being left as-is (i.e., unheated), and one heated for 1 hr at 300° C. and then subjected to a tensile strength test.

Next, one of the unused sample was heated for 1 hr at 300° C. and then subjected to a bending test.

Lastly, the remaining unused sample was thermally compressed onto a film and evaluated for wrinkling and curling.

Details of the measurements and evaluations follow below.

### (2) Measurement of Surface Roughness

The surface roughness Rz of the untreated electrodeposited copper foil of the working examples, comparative examples, and reference example was measured using contact-type surface roughness tester. The surface roughness is given as Rz (10-spot average roughness) as defined in JIS-B-0601. The reference length was 0.8 mm. Using this measurement device, three measurement values, Ra, Ry, and Rz, can be obtained in one measurement. Rz was used as the surface roughness in the present invention. Table 2 gives the results for the working examples, the comparative examples, and the reference example.

(3) Using EBSD Measurement to Calculate the Number of Crystal Grains with a Grain Diameter of Less than 2 μm and Calculate the Crystal Orientation Ratio

The untreated electrodeposited copper foil of the working examples, comparative examples, and reference example were divided into two, one part being left as-is (i.e., unheated) and the other heated for 1 hr at 300° C. in a nitrogen atmosphere. The M-surface of both parts, which was etched with chemicals, was used as the measurement surface. The number of crystal grains with a grain diameter of less than 2 μm was calculated, and the crystal orientation ratio was calculated, under measurement conditions of a step size of 0.5 μm in a visual field 300 μm×300 μm. OIM, an analytical software by TSL, was used for calculation and analysis.

A misalignment of 5° or greater was defined as a grain boundary when counting crystal grains, and the diameter of a circle having the same area as the area of the crystal grains was used as the crystal grain diameter. The results are shown in Table 2.

For the crystal orientation ratio, a misalignment in crystal planes up to 10° inclusive was deemed to be the same crystal plane. Measurements were made for the (001) plane, the (011) plane, the (210) plane, the (311) plane, and the (331) plane. After that, the total planes for

the total of the (001) plane and the (311) plane,

the total of the (011) plane and the (210) plane, and

the total of the (331) plane and the (210) plane

were calculated. The results are shown in Table 4.

### (4) Evaluation of Fine Pattern Characteristics

The fine pattern characteristics were evaluated for the untreated electrodeposited copper foil of the working examples, the comparative examples, and reference example. The evaluation was conducted using a circuit pattern made by compressing the M-surface side to a polyimide film using a heat press for 1 hr at 300° C., masking the S-surface side with an L/S (line and space) of 25 μm/25 μm, and then performing etching using a copper chloride solution. The evaluation was made by observing the circuit pattern from directly above with a microscope and measuring the difference between the upper and lower limits of the widths of circuits having a length of 100 μm. Upper/lower limit differences in circuit width of less than 1 μm are indicated by a ⊚ (particularly good), less than 3 μm by a ∘ (pass), and everything else by a x (fail). Table 2 gives the results.

TABLE 2

| | | Crystal | | | |
|---|---|---|---|---|---|
| | | diameter | | | |
| | | Number of | Surface | | |
| | | crystals | roughness | | |
| | | with a | M- | S- | |
| | | diameter | surface | surface | Fine pattern |
| | | of 2 μm | Rz | Rz | character- |
| No. | Heating | or less | (μm) | (μm) | istics |
| Working | Before | 17458 | 1.59 | 1.65 | ⊚ |
| example-1 | heating | | | | |
| | 300° C. × 1 | 10587 | | | |
| | hour | | | | |
| Working | Before | 15478 | 1.35 | 1.62 | ⊚ |
| example-2 | heating | | | | |
| | 300° C. × 1 | 6215 | | | |
| | hour | | | | |
| Working | Before | 22156 | 1.89 | 1.59 | ⊚ |
| example-3 | heating | | | | |
| | 300° C. × 1 | 14248 | | | |
| | hour | | | | |
| Working | Before | 19198 | 1.75 | 1.61 | ⊚ |
| example-4 | heating | | | | |
| | 300° C. × 1 | 9867 | | | |
| | hour | | | | |
| Working | Before | 16847 | 1.55 | 1.58 | ⊚ |
| example-5 | heating | | | | |
| | 300° C. × 1 | 12589 | | | |
| | hour | | | | |
| Working | Before | 11847 | 1.36 | 1.63 | ⊚ |
| example-6 | heating | | | | |
| | 300° C. × 1 | 5987 | | | |
| | hour | | | | |
| Working | Before | 15278 | 3.46 | 3.59 | ◯ |
| example-7 | heating | | | | |
| | 300° C. × 1 | 6021 | | | |
| | hour | | | | |
| Comparative | Before | 32556 | 3.84 | 1.60 | ◯ |
| example-1 | heating | | | | |
| | 300° C. × 1 | 18123 | | | |
| | hour | | | | |
| Comparative | Before | 29984 | 3.43 | 1.64 | ◯ |
| example-2 | heating | | | | |
| | 300° C. × 1 | 17653 | | | |
| | hour | | | | |
| Comparative | Before | 30012 | 2.13 | 1.63 | ⊚ |
| example-3 | heating | | | | |
| | 300° C. × 1 | 14623 | | | |
| | hour | | | | |
| Comparative | Before | 21222 | 2.56 | 1.61 | ⊚ |
| example-4 | heating | | | | |
| | 300° C. × 1 | 19628 | | | |
| | hour | | | | |
| Comparative | Before | 26871 | 2.76 | 1.66 | ⊚ |
| example-5 | heating | | | | |
| | 300° C. × 1 | 20019 | | | |
| | hour | | | | |
| Comparative | Before | 36666 | 1.77 | 1.68 | ◯ |
| example-6 | heating | | | | |
| | 300° C. × 1 | 4195 | | | |
| | hour | | | | |
| Reference | Before | 23456 | 0.96 | 1.59 | X |
| Example | heating | | | | |
| | 300° C. × 1 | 2728 | | | |
| | hour | | | | |

### (5) Tensile Strength Test

The unprocessed electrodeposited copper foil of the working examples, and comparative examples were divided into two, one part being left as-is (i.e., unheated) and the other heated for 1 hr at 300° C. in a nitrogen atmosphere. Thereafter, both were cut into test pieces of 6 inch long and 0.5 inch wide and subjected to tensile strength, elongation, and 0.2% yield strength tests using a tensile strength tester. The tension speed was 50 mm/min. 0.2% yield strength is obtained by, in a curve of the relationship between strain and stress, drawing a tangent line on the curve at a point where the strain is 0%, then drawing a straight line parallel to the tangent line at a point where the strain is 0.2%, and dividing the stress of a point where the straight line and the curve intersected by the cross sectional area. Table 3 gives the results for the working examples and the comparative examples.

### (6) Bending Test

The unprocessed electrodeposited copper foil of the working examples and comparative examples were heated for 1 hr at 300° C. in a nitrogen atmosphere. They were thereafter cut into 130 mm×15 mm test pieces and subjected to an MIT bending test until the copper foil broke under the following conditions. This bending test involves placing a load on the samples which is sufficiently light not to create any flexing in the samples, allowing evaluation of bending performance as a flexible wiring board, which is the object of the present invention, by testing fatigue breaking, and not ductile breaking.

The bending test conditions were:

Bending radius R: 0.38 mm

Bending angle: ±135°

Bending speed: 17.5 times/min

Load: 10 g

The measurement results were evaluated with a ⊚ (particularly good) for samples which had not broken after 1500 bends, a ∘ (pass) for samples which had not broken after 800 bends, and a x (fail) for samples which broke at less then 800 bends. Table 3 gives the results.

TABLE 3

| | Mechanical characteristics | | | | | | |
|---|---|---|---|---|---|---|---|
| | | | | After heating | | | |
| | Before heating | | | 300° C. × 1 hour | | | |
| | | | 0.2% | | | 0.2% | Bending |
| | Tensile | | yield | Tensile | | yield | resistance |
| | strength | Elongation | strength | strength | Elongation | strength | After heating |
| No. | (MPa) | (%) | (MPa) | (MPa) | (%) | (MPa) | 300° C. × 1 hour |
| Working | 325 | 10.1 | 222 | 198 | 12.3 | 120 | ⊚ |
| example-1 | | | | | | | |
| Working | 315 | 10.5 | 212 | 189 | 11.5 | 108 | ⊚ |
| example-2 | | | | | | | |
| Working | 353 | 8.5 | 263 | 233 | 14.1 | 135 | ◯ |
| example-3 | | | | | | | |
| Working | 333 | 10.5 | 240 | 196 | 10.9 | 119 | ⊚ |
| example-4 | | | | | | | |
| Working | 324 | 10.3 | 235 | 213 | 13.5 | 124 | ⊚ |
| example-5 | | | | | | | |
| Working | 298 | 9.5 | 205 | 191 | 12.3 | 109 | ⊚ |
| example-6 | | | | | | | |
| Working | 322 | 10.1 | 218 | 192 | 11.2 | 112 | ◯ |
| example-7 | | | | | | | |
| Comparative | 444 | 5.6 | 326 | 249 | 18.3 | 141 | X |
| example-1 | | | | | | | |
| Comparative | 414 | 6.5 | 300 | 232 | 15.8 | 137 | X |
| example-2 | | | | | | | |
| Comparative | 415 | 6.9 | 303 | 206 | 13.9 | 125 | ⊚ |
| example-3 | | | | | | | |
| Comparative | 343 | 9.8 | 254 | 241 | 15.1 | 145 | X |
| example-4 | | | | | | | |
| Comparative | 394 | 7.6 | 281 | 255 | 15.4 | 148 | X |
| example-5 | | | | | | | |
| Comparative | 485 | 4.5 | 370 | 201 | 14.6 | 105 | ⊚ |
| example-6 | | | | | | | |

(7) Evaluation of Wrinkling and Curling after Film Adhesion

The untreated electrodeposited copper foil of the working examples, comparative examples, and reference example was evaluated for wrinkling and curling after film adhesion. The evaluation was carried out by cutting the copper foil with the film adhered, made by compressing the M-surface side to a polyimide film for 1 hr at 300° C. with a thermal press and then cutting the obtained product into 30 cm×30 cm pieces. A ∘ (pass) is used for no wrinkles upon visual inspection and a x (fail) for wrinkles. Evaluation for curling was performed by placing a 20 cm×20 cm metal jig on the sample on a flat surface and securing the center, and then measuring curling with a ruler on all four sides. A ∘ (pass) indicates that there were 5 mm or less curls on all four sides. If there was a curling of more than 5 mm, a x (fail) is given. Table 4 shows the results.

TABLE 4

| | | Heat-treatment | | Ratio | Wrinkling/ | |
|---|---|---|---|---|---|---|
| | | Before | | of | curling | |
| | Total of crystal | heating | 300° C. × 1 hour | change | evaluation | |
| No. | orientation ratios | (%) | (%) | (%) | Wrinkling | Curling |
| Working | (001) plane + | 38.0 | 41.5 | 9.2 | ◯ | ◯ |
| example-1 | (311) plane | | | | | |
| | (011) plane + | 29.1 | 25.8 | −11.3 | | |
| | (210) plane | | | | | |
| | (331) plane + | 36.4 | 32.8 | −9.9 | | |
| | (210) plane | | | | | |
| Working | (001) plane + | 32.7 | 33.9 | 3.7 | ◯ | ◯ |
| example-2 | (311) plane | | | | | |
| | (011) plane + | 33.9 | 31.0 | −8.6 | | |
| | (210) plane | | | | | |
| | (331) plane + | 42.6 | 39.5 | −7.3 | | |
| | (210) plane | | | | | |
| Working | (001) plane + | 34.5 | 40.1 | 16.2 | ◯ | ◯ |
| example-3 | (311) plane | | | | | |
| | (011) plane + | 35.1 | 32.4 | −7.7 | | |
| | (210) plane | | | | | |
| | (331) plane + | 42.6 | 39.5 | −7.3 | | |
| | (210) plane | | | | | |
| Working | (001) plane + | 36.3 | 37.8 | 4.1 | ◯ | ◯ |
| example-4 | (311) plane | | | | | |
| | (011) plane + | 29.0 | 27.8 | −4.1 | | |
| | (210) plane | | | | | |
| | (331) plane + | 36.2 | 34.3 | −5.2 | | |
| | (210) plane | | | | | |
| Working | (001) plane + | 22.4 | 30.6 | 36.3 | ◯ | X |
| example-5 | (311) plane | | | | | |
| | (011) plane + | 44.8 | 36.3 | −19.0 | | |
| | (210) plane | | | | | |
| | (331) plane + | 53.7 | 44.4 | −17.3 | | |
| | (210) plane | | | | | |
| Working | (001) plane + | 35.3 | 36.5 | 3.4 | ◯ | ◯ |
| example-6 | (311) plane | | | | | |
| | (011) plane + | 33.4 | 33.6 | 0.6 | | |
| | (210) plane | | | | | |
| | (331) plane + | 40.1 | 39.9 | −0.5 | | |
| | (210) plane | | | | | |
| Working | (001) plane + | 38.0 | 41.5 | 9.2 | ◯ | ◯ |
| example-7 | (311) plane | | | | | |
| | (011) plane + | 29.1 | 26.9 | −7.6 | | |
| | (210) plane | | | | | |
| | (331) plane + | 36.4 | 32.8 | −9.9 | | |
| | (210) plane | | | | | |
| Comparative | (001) plane + | 37.5 | 41.4 | 10.4 | ◯ | ◯ |
| example-1 | (311) plane | | | | | |
| | (011) plane + | 36.2 | 33.5 | −7.5 | | |
| | (210) plane | | | | | |
| | (331) plane + | 42.9 | 39.5 | −7.9 | | |
| | (210) plane | | | | | |
| Comparative | (001) plane + | 32.3 | 34.0 | 5.3 | ◯ | ◯ |
| example-2 | (311) plane | | | | | |
| | (011) plane + | 28.6 | 29.3 | 2.4 | | |
| | (210) plane | | | | | |
| | (331) plane + | 40.2 | 38.4 | −4.5 | | |
| | (210) plane | | | | | |
| Comparative | (001) plane + | 22.4 | 30.6 | 36.6 | ◯ | X |
| example-3 | (311) plane | | | | | |
| | (011) plane + | 44.8 | 36.3 | −19.0 | | |
| | (210) plane | | | | | |
| | (331) plane + | 53.7 | 44.4 | −17.3 | | |
| | (210) plane | | | | | |
| Comparative | (001) plane + | 26.6 | 29.6 | 11.3 | ◯ | ◯ |
| example-4 | (311) plane | | | | | |
| | (011) plane + | 40.7 | 42.1 | 3.4 | | |
| | (210) plane | | | | | |
| | (331) plane + | 49.6 | 48.5 | −2.2 | | |
| | (210) plane | | | | | |
| Comparative | (001) plane + | 27.6 | 39.0 | 41.3 | ◯ | X |
| example-5 | (311) plane | | | | | |
| | (011) plane + | 40.2 | 35.2 | −12.4 | | |
| | (210) plane | | | | | |
| | (331) plane + | 42.3 | 40.9 | −3.3 | | |
| | (210) plane | | | | | |
| Comparative | (001) plane + | 39.4 | 25.2 | −36.0 | X | X |
| example-6 | (311) plane | | | | | |
| | (011) plane + | 18.6 | 20.2 | 8.6 | | |
| | (210) plane | | | | | |
| | (331) plane + | 28.9 | 36.4 | 26.0 | | |
| | (210) plane | | | | | |
| Reference | (001) plane + | 23.6 | 39.0 | 65.6 | X | X |
| Example | (311) plane | | | | | |
| | (011) plane + | 31.2 | 18.2 | −41.7 | | |
| | (210) plane | | | | | |
| | (331) plane + | 45.2 | 21.9 | −51.5 | | |
| | (210) plane | | | | | |

* Calculation for ratio of change:
{Total of orientation ratio after heating for “300° C. × 1 hour”} ÷ {Total of orientation ratio “before heating”} * 100 − 100
Evaluation of wrinkling: ◯ (pass) for no wrinkles; and × (fail) for wrinkles
Evaluation of curling: ◯ (pass), if there were 5 mm or less curls on all four sides; and x (fail), if there was a curling of more than 5 mm

As is clear from Table 2, in Working Examples 1 to 6, the number of crystal grains having a grain diameter of less than 2 μm before heating within a range of 300 μm×300 μm was 10,000 or greater and 25,000 or less, the yield strength was not too low, the crystal structure was not too fine, and handling was excellent in manufacturing and processing lines. Moreover, the number of crystal grains having a grain diameter of less than 2 μm after heating for 1 hr at 300° C. within a range of 300 μm×300 μm was 5,000 or greater and 15,000 or less, and there were few grain boundaries that could act as origin points for cracks during folding or bending. As can be seen from Table 3, bending characteristics were excellent, excessive coarseness of the crystal grain structure due to heating was minimized, and fine pattern characteristics were excellent.

Furthermore, in Working Example 7, the number of crystal grains with a grain diameter less than 2 μm was the same as in Working Example 2 both before and after heating for 1 hr and 300° C., but the surface was very rough, there was significant unevenness, and thus fine pattern characteristics were poor.

As can be seen from Table 2, in Comparative Examples 1, 2, 3, 5, and 6, the number of crystal grains less than 2 μm in diameter within a range of 300 μm×300 μm before heating exceeded 25,000, and the crystal grain structure was excessively fine, causing insufficient ductility and resulting in a tendency to crack in manufacturing and processing lines, which made handling difficult.

Furthermore, in Comparative Examples 1, 2, 4, and 5, the number of crystal grains less than 2 μm in diameter after heating for 1 hr at 300° C. within a range of 300 μm×300 μm exceeded 15,000. There was no problem with the fine pattern characteristics, but the crystal grain structure was excessively fine, there was a great deal of grain boundaries which could act as origin points for cracks during bending, and, as is clear from Table 3, there was insufficient bending.

Furthermore, in Comparative Example 6, the number of crystal grains with a diameter less than 2 μm after heating for 1 hr at 300° C. within a range of 300 μm×300 μm was less than 5,000. As can be seen from Table 2, the surface roughness was the same as the Working Examples, but the crystal grain structure was excessively coarse, which adversely effected the fine pattern characteristics.

As can be seen from Table 3, Working Examples 1, 2 and 4 to 7 had a 0.2% yield strength (MPa) after heating for 1 hr at 300° C. of less than or equal to 131, which was the value in equation 1 for a foil thickness of 12 μm. These working examples indicated a soft copper foil with a low modulus of elasticity due to the heating applied during the film adhesion step, which is one of the manufacturing steps of a wiring board. Of these, Working Examples 1, 2 and 4 to 6 showed excellent bending in the bending test performed after heating for 1 hr at 300° C., and it was shown that the softness due to the heating had a good effect.

On the other hand, in Working Example 7, the surface roughness Rz of the M-surface and the S-surface exceeded 3.0 μm and there was significant unevenness. Therefore, cracks from the surface tended to appear during bending. The results from the bending test were therefore poor.

Because the 0.2% yield strength of Working Example 3 was higher than 131, the copper foil was not soft with a low modulus of elasticity due to heating. The results during the bending test were therefore poor.

As can be seen from Table 3, Comparative Examples 3 and 6 had a 0.2% yield strength (MPa) after heating for 1 hr at 300° C. of less than or equal to 131, which was the value in equation 1 for a foil thickness of 12 μm. Hence, these comparative examples resulted in soft copper foil with a low modulus of elasticity, showing excellent bending characteristics in the bending test after heating.

At the same time, Comparative Examples 1 and 2 had a surface roughness Rz on the M-surface of greater than 3.0 μm, with significant unevenness. Therefore, cracks from the surface tended to appear during bending, and because the 0.2% yield strength was greater than 131, the resulting copper foil was not soft with a low modulus of elasticity due to heating, and failed the bending test.

Because the 0.2% yield strength was significantly higher than 131 in Comparative Examples 4 and 5, the copper foil was not soft with a low modulus of elasticity due to heating. The results during the bending test were therefore poor.

As is clear from Table 4, the ratio of change before to after heating for 1 hr at 300° C. for the total of the (001) plane and the (311) plane, the total of the (011) plane and the (210) plane, and the total of the (331) plane and the (210) plane in the crystal orientation ratio through EBSD measurement for Working Examples 1 to 4 and 6 and 7 was ±20% or less throughout, and wrinkling and curling were suppressed during the film adhesion step.

At the same time, Working Example 5 had a ratio of change of the total of the (001) plane and the (311) plane exceeded ±20%, and suffered from curling during the film adhesion step.

As is clear from Table 4, the ratio of change before to after heating for 1 hr at 300° C. for the total of the (001) plane and the (311) plane, the total of the (011) plane and the (210) plane, and the total of the (331) plane and the (210) plane in the crystal orientation ratio through EBSD measurement in Comparative Examples 1, 2 and 4 was ±20% or less throughout, and wrinkling and curling were suppressed during the film adhesion step.

On the other hand, the ratio of change before to after heating for 1 hr at 300° C. for the total of the (001) plane and the (311) plane, the total of the (011) plane and the (210) plane, and the total of the (331) plane and the (210) plane in the crystal orientation ratio through EBSD measurement in Comparative Examples 3, 5 and 6 was more than ±20% in at least one case, and wrinkling and curling occurred during the film adhesion step.

As is clear from Table 2, in the reference example, the number of crystal grains with a grain diameter less than 2 μm after heating for 1 hr at 300° C. was significantly less than 5,000. The crystal grins were therefore excessively coarsened overall, and the fine pattern characteristics were significantly poorer than the working examples, despite having a surface roughness which was extremely low and smooth, as is clear from Table 2.

Furthermore, the ratio of change before to after heating for 1 hr at 300° C. for the total of the (001) plane and the (311) plane, the total of the (011) plane and the (210) plane, and the total of the (331) plane and the (210) plane in the crystal orientation ratio through EBSD measurement in the reference example was significantly more than ±20% in at least one case, and wrinkling and curling occurred during the film adhesion step.

Note that the difference between the number of crystal grains with a grain diameter of less than 2 μm after heating in the working examples and the reference example could not be explained in detail. The difference is, however, thought to originate in the strain remaining in the copper foil before heating (unprocessed). The number of crystal grains with a grain diameter less than 2 μm before heating was greater in the reference example than in the working examples, and this is why it was thought that there was more strain accumulated in the copper foil in the reference example. Hence, the strain is expressed as “drive force” for crystal growth during heating, and the reference example is therefore estimated to undergo a greater decrease in the number of crystal grains with a grain diameter of less than 2 μm than the working examples.

Furthermore, because the composition of the additives in the reference example was different from that of the working examples, the crystal orientation ratio as measured by EBSD after heating for 1 hr at 300° C. was significantly different from that of the working examples. The crystal orientation ratio depends heavily on the composition of the additives and the manufacturing method.

On the basis of the results of the working examples, the present invention can provide an electrodeposited copper foil for a flexible wiring board, wherein handling in manufacturing and processing lines is easy, good bending and flexing are provided with heating during a film adhesion step, small electric devices can be accommodated, excessive coarsening of a crystal grain structure is minimized, and excellent fine pattern characteristics are provided.

Furthermore, because the electrodeposited copper foil of the present invention has excellent fine pattern characteristics, the present invention can also be applied to wiring boards which are not required to be flexible.

The manufacturing method for the electrodeposited copper foil of the present invention comprises forming a foil by copper sulfate electrolyte in which MPS-Na or SPS-Na as a compound having a mercapto group within a concentration range of 0.25 ppm or greater and 7.5 ppm or less, HEC as a polymer polysaccharide within a range of 3.0 ppm or greater and 30 ppm or less, and chlorine ion within a range of 1 ppm or greater and 20 ppm or less are added.

Furthermore, after treating the surface of the electrodeposited copper foil of the present invention, such as anti-rusting or the like, the surface smoothness is excellent if laminated with a film or the like, so it can also be suitably used as a flexible wiring board for high frequencies. Furthermore, it is also possible to provide one face with a roughed layer with the goal of improving adhesion due to the anchor effect. Note that roughening is not necessary if the target performance can be achieved without roughening.

### INDUSTRIAL APPLICABILITY

The electrodeposited copper foil of the present invention is also suitable as a wiring board for high frequencies using the skin effect by utilizing the smoothness of the surface. Since it has good bending and flexing characteristics, it provides effectiveness as a high-frequency wiring board which requires such characteristics.

Moreover, the electrodeposited copper foil of the present invention can be used as a copper foil for a battery. More particularly, the electrodeposited copper foil of the present invention can be used as a negative electrode collector in a lithium-ion secondary battery which uses a tin or silicon activated substance with large expansion and contraction, due to its good elongation characteristics.

### REFERENCE NUMERALS

1: Anode
2: Cathode
3: Electrolyte
4: Untreated electrodeposited copper foil

What is claimed is:

1. An electrodeposited copper foil, wherein a crystal distribution before heating (unprocessed) is such that a number of crystal grains less than 2 μm in diameter within a range of 300 μm×300 μm is 10,000 or greater and 25,000 or less, and a crystal distribution after heating for 1 hr at 300° C. is such that the number of crystal grains less than 2 μm in diameter within a range of 300 μm×300 μm is 5,000 or greater and 15,000 or less.

2. The electrodeposited copper foil according to claim 1, wherein a crystal orientation ratio (%) as measured by EBSD before heating (unprocessed) to that after heating for 1 hr at 300° C. of the copper foil is such that ratios of change after heating relative to before heating for the following totals:
a total of a (001) plane and a (311) plane,
a total of a (011) plane and a (210) plane, and
a total of a (331) plane and a (210) plane
are all within ±20%.

3. The electrodeposited copper foil according to any one of claims 1 to 2, wherein a 0.2% yield strength (MPa) of the electrodeposited copper foil after heating for 1 hr at 300° C. is less than or equal to a value y in the equation 1, where x is a thickness (μm) of the foil:
y=215*x^{-0.2} (Equation 1)

4. The electrodeposited copper foil according to any one of claims 1 to 3, wherein a surface roughness Rz of an M-surface of the electrodeposited copper foil is less than 3.0 μm and a surface roughness Rz of an S-surface is less than 3.0 μm.

5. A wiring board manufactured using the electrodeposited copper foil according to any one of claims 1 to 4.

6. A flexible wiring board manufactured using the electrodeposited copper foil according to any one of claims 1 to 4.
